(19) United States
(12) Patent Application Publication
(10) Pub. No.: US 2015/0130501 A1
(43) Pub. Date: May 14, 2015

(54) ADJUSTABLE RESISTOR DEVICE

(71) Applicants: Hon Hai Precision Industry Co., Ltd., New Taipei (TW); Hong Fu Jin Precision Industry (ShenZhen) Co., Ltd., Shenzhen (CN)

(72) Inventor: JIA-QI DONG, Shenzhen (CN)

(73) Assignees: Hon Hai Precision Industry Co., Ltd., New Taipei (TW); Hong Fu Jin Precision Industry (ShenZhen) Co., Ltd., Shenzhen (CN)

(21) Appl. No.: 14/140,639

(22) Filed: Dec. 26, 2013

(30) Foreign Application Priority Data
Nov. 11, 2013 (CN) 2013105563728

(51) Int. Cl. G01R 1/20; G01R 31/28; H03H 7/38

(52) U.S. Cl. CPC G01R 1/203; H03H 7/38; G01R 31/281; G01R 31/2818
USPC 324/763.01

(57) ABSTRACT

An adjustable resistor device includes a first pin, a second pin, a resistance-adjusting branch circuit, and a resistance display circuit. The first and second pins are configured to connect to an external circuit. The resistance-adjusting branch circuit is connected between the first pin and the second pin, and provides resistors for testing the external circuit. The resistance display circuit displays a resistance of the resistance display circuit.

### BACKGROUND

1. Technical Field

The present disclosure relates to an adjustable resistor device, and particularly to an adjustable resistor device for testing a circuit board.

2. Description of Related Art

During manufacturing, repairing, and testing of circuit boards, a plurality of resistors having different resistances from each other is individually connected to a test circuit of the circuit board, and the circuit board is repeatedly tested, so as to determine which resistor meets a work requirement of the circuit board. However, manually disassembling and assembling the resistors to the circuit board wastes a lot of time, and the test circuit may be damaged in the process.

Therefore, what is needed is an adjustable resistor device that can overcome the described limitations.

### BRIEF DESCRIPTION OF THE DRAWINGS

FIG. 1 is a circuit diagram of an embodiment of an adjustable resistor device.

FIG. 2 is a schematic structural view of the adjustable resistor device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

Reference will now be made to the drawings to describe embodiments of the present disclosure.

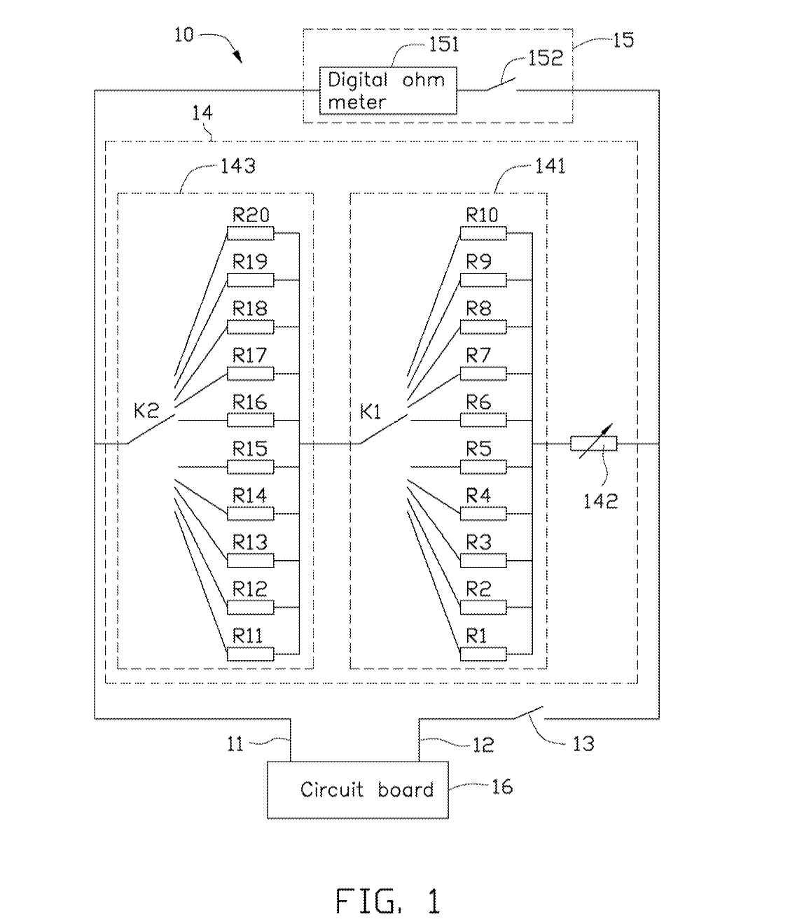

FIG. 1 illustrates one embodiment of an adjustable resistor device 10. The adjustable resistor device 10 comprises a first pin 11, a second pin 12, a debug control switch 13, a resistance-adjusting branch circuit 14, and a resistance display circuit 15. The first pin 11 and the second pin 12 each connect to an external circuit. In one embodiment, the external circuit is a circuit board 16 to be tested. The resistance-adjusting branch circuit 14 is connected between the first pin 11 and the second pin 12, and is configured to provide resistors for debugging the circuit board 16. The debug control switch 13 is connected between the second pin 12 and the resistance-adjusting branch circuit 14. The resistance display circuit 15 is connected to the resistance-adjusting branch circuit 14 in parallel, and is configured to display a resistance value of the resistance-adjusting branch circuit 14. In other embodiments, the debug control switch 13 is connected between the first pin 11 and the resistance-adjusting branch circuit 14.

The resistance display circuit 15 comprises a digital ohm meter 151 and a display control switch 152. The digital ohm meter 151 and the display control switch 152 are connected between the first pin 11 and the second pin 12 in series. When the debug control switch 13 is switched on and the display control switch 15 is switched off, the resistance-adjusting branch circuit 14 provides resistors for testing the circuit board 16. When the display control switch 15 is switched on and the debug control switch 13 is switched off, the digital ohm meter 151 displays a resistance of the resistance-adjusting branch circuit 14.

The resistance-adjusting branch circuit 14 comprises a first resistance-adjusting module 141, a second-resistance-adjusting module 142, and a third resistance-adjusting module 143. A resistance of the first resistance-adjusting module 141 is stepwise adjustable. The first resistance-adjusting module 141 comprises a plurality of resistors

R1 through R0 and a first resistance selection switch K1. Resistances of the resistors R1 through R10 differ from each other. The first resistance selection switch K1 is manually switched to connect one of the resistors R1 through R0 between the second resistance-adjusting module 142 and the third resistance-adjusting module 143. In one embodiment, a number of the resistors R1 through R10 is ten. The resistors R1 through R10 are respectively defined as a first resistor R1, a second resistor R2, a third resistor R3, a fourth resistor R4, a fifth resistor R5, a sixth resistor R6, a seventh resistor R7, an eighth resistor R8, a ninth resistor R9, and a tenth resistor R10. In one embodiment, a resistance of the first resistor R1 equals 0 Ohms (Ω). Resistances of the second through tenth resistors R2-R10 are XΩ, 2XΩ, 3XΩ, 4XΩ, 5XΩ, 6XΩ, 7XΩ, 8XΩ, and 9XΩ, respectively, wherein X is greater than zero.

A resistance of the second resistance-adjusting module 142 is slidably adjustable. In one embodiment, the second resistance-adjusting module 142 is a sliding resistor. A resistance range of the second resistance-adjusting module 142 is not less than 0Ω and is not more than XΩ.

A resistance of the third resistance-adjusting module 143 is stepwise adjustable. The third resistance-adjusting module 143 comprises a plurality of resistors R11 through R20 and a second resistance selection switch K2. Resistances of the resistors R11 through R20 differ from each other. The second resistance selection switch K2 is manually switched to connect one of the resistors R11 through R20 between the first pin 11 and the first resistance-adjusting module 141. The resistors R11 through R20 are respectively defined as an eleventh resistor R11, a twelfth resistor R12, a thirteenth resistor R13, a fourteenth resistor R14, a fifteenth resistor R15, a sixteenth resistor R16, a seventeenth resistor R17, an eighteenth resistor R18, a nineteenth resistor R19, and a twentieth resistor R20. In one embodiment, a resistance of the eleventh resistor R11 is 0Ω. Resistances of the twelfth through twentieth resistors R12-R20 are 10XΩ, 20XΩ, 30XΩ, 40XΩ, 50XΩ, 60XΩ, 70XΩ, 80XΩ, and 90XΩ, respectively, wherein X is greater than zero.

In one embodiment, X equals 10 kiloOhms (kΩ). Thus, the resistance range of the second resistance-adjusting module 142 is between 0Ω and 10 kΩ, and a resistance range of the resistance-adjusting branch circuit 14 is between 0Ωand 1000 kΩ.

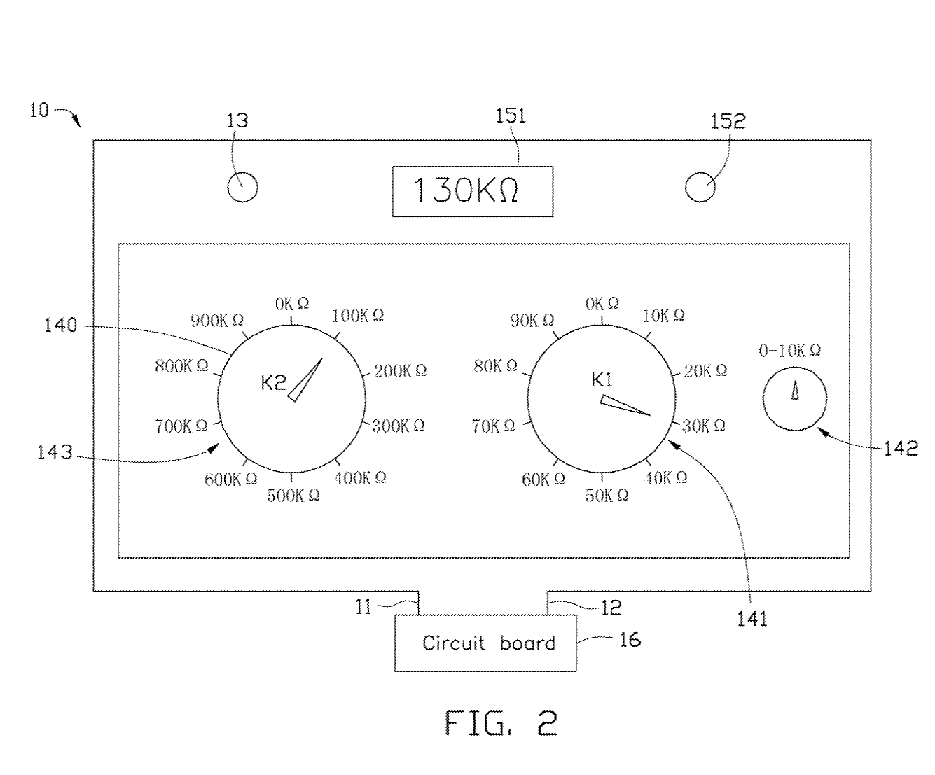

FIG. 2 is a schematic structural view of the adjustable resistor device 10. In one embodiment, the first, second, and third resistance-adjusting modules 141, 142, and 143 are manual regulating modules. Each of the first, second, and third resistance-adjusting modules 141, 142, and 143 further comprises a manual regulating knob 140.

In use, when the circuit board 16 is tested, the first pin 11 and the second pin 12 are connected to a test circuit of the circuit board 16. The display control switch 152 is switched off, and the debug control switch 13 is switched on. The manual regulating knobs 140 of the first, second, and third resistance-adjusting modules 141, 142, and 143 are manually adjusted, so as to select the resistance connected to the circuit board 16, and the circuit board 16 is tested. When the selected resistance meets a work requirement of the circuit board 16, the debug control switch 13 is switched off, and the display control switch 152 is switched on. The digital ohm meter 151 displays the current resistance of the resistance-adjusting branch circuit 141, and the displayed resistance is set as the resistance of the circuit board 16.

Since the resistance-adjusting branch circuit 14 of the adjustable resistor device 10 provides a plurality of resistors having different resistances from each other for testing the circuit board 16, and the resistance display circuit 15 displays the resistance meeting the work requirement of the circuit board 16, there is no need to repeatedly manually disassemble and assemble resistors to the circuit board 16 during the testing process of the circuit board 16. Accordingly, a testing time is reduced, and the test circuit of the circuit board 16 is less likely to be damaged during the testing process.

In addition, due to a cooperation of the debug control switch 13 and the display control switch 152, a resistor of the resistance display circuit 15 does not affect the test of the circuit board 16, and the circuit board 16 does not affect a resistance of the resistance-adjusting branch circuit 14. Thus, testing of the circuit board 16 is more accurate.

It is believed that the present embodiments and their advantages will be understood from the foregoing description, and it will be apparent that various changes may be made thereto without departing from the spirit and scope of the present disclosure or sacrificing all of its material advantages.

What is claimed is:

1. An adjustable resistor device, comprising:
a first pin configured to connect to an external circuit;
a second pin configured to connect to the external circuit;
a resistance-adjusting branch circuit connected between the first pin and the second pin, and providing resistors for debugging the external circuit; and
a resistance display circuit displaying a resistance of the resistance-adjusting branch circuit.

2. The adjustable resistor device of claim 1, further comprising a debug control switch, wherein the debug control switch is connected between the first pin and the resistance-adjusting branch circuit or is connected between the second pin and the resistance-adjusting branch circuit.

3. The adjustable resistor device of claim 2, wherein the resistance display circuit and the resistance-adjusting branch circuit are connected each other in parallel, and the resistance display branch circuit comprises a digital ohm meter and a display control switch connected to the digital ohm meter in series.

4. The adjustable resistor device of claim 3, wherein when the debug control switch is switched on and the display control switch is switched off, the resistance-adjusting branch circuit provides the resistors for debugging the external circuit.

5. The adjustable resistor device of claim 3, wherein when the display control switch is switched on and the debug control switch is switched off, the digital ohm meter displays the resistance of the resistance-adjusting branch circuit.

6. The adjustable resistor device of claim 1, wherein the resistance-adjusting branch circuit comprises a first resistance-adjusting module and a second resistance-adjusting module connected to the first resistance-adjusting module in series; a resistance of the first resistance-adjusting module is stepwise adjustable; the first resistance-adjusting module comprises a first resistance selection switch and a plurality of resistors having different resistances from each other; the first resistance selection switch selectively connects one of the resistors of the first resistance-adjusting module between the second resistance-adjusting module and the third resistance-adjusting module; the lowest resistances of two of the resistors of the first resistance-adjusting module are respectively 0Ω and XΩ, X is more than 0; the second resistance-adjusting module is slidably adjustable; a resistance range of the second resistance-adjusting module is not less than 0Ω and is not more than XΩ.

7. The adjustable resistor device of claim 6, wherein the first resistance-adjusting module comprises ten resistors; the ten resistors are respectively defined as a first resistor, a second resistor, a third resistor, a fourth resistor, a fifth resistor, a sixth resistor, a seventh resistor, an eighth resistor, a ninth resistor, and a tenth resistor; the resistance of the first resistor equals 0Ω; the resistance of the second resistor equals XΩ; the resistance of the third resistor is twice that of the second resistor; the resistance of the fourth resistor is three times that of the second resistor; the resistance of the fifth resistor is four times that of the second resistor; the resistance of the sixth resistor is five times that of the second resistor; the resistance of the seventh resistor is six times that of the second resistor; the resistance of the eighth resistor is seven times that of the second resistor; the resistance of the ninth resistor is eight times that of the second resistor; the resistance of the tenth resistor is nine times that of the second resistor.

8. The adjustable resistor device of claim 7, wherein the resistance-adjusting branch circuit further comprises a third resistance-adjusting module connected to the first, second resistance-adjusting module in series; the third resistance-adjusting module is stepwise adjustable; the third resistance-adjusting module comprises a second resistance selection switch and a plurality of resistors having different resistances from each other; the second resistance selection switch selectively connects one of the resistors of the third resistance-adjusting module between the first resistance-adjusting module and the first pin; the lowest resistances of two of the resistors of the third resistance-adjusting module are respectively 0Ω and 10XΩ.

9. The adjustable resistor device of claim 8, wherein the third resistance-adjusting module comprises ten resistors; the ten resistors of the third resistance-adjusting module are respectively defined as a eleventh resistor, a twelfth resistor, a thirteenth resistor, a fourteenth resistor, a fifteenth resistor, a sixteenth resistor, a seventeenth resistor, an eighteenth resistor, a nineteenth resistor, and a twentieth resistor; the resistance of the eleventh resistor equals 0Ω; the resistance of the twelfth resistor equals 10XΩ; the resistance of the thirteenth resistor is twice that of the twelfth resistor; the resistance of the fourteenth resistor is three times that of the twelfth resistor; the resistance of the fifteenth resistor is four times that of the twelfth resistor; the resistance of the sixteenth resistor is five times that of the twelfth resistor; the resistance of the seventeenth resistor is six times that of the twelfth resistor; the resistance of the eighteenth resistor is seven times that of the twelfth resistor; the resistance of the nineteenth resistor is eight times that of the twelfth resistor; the resistance of the twentieth resistor is nine times that of the twelfth resistor.

10. The adjustable resistor device of claim 8, wherein XΩ is 10 KΩ.
